(19) United States
(12) Patent Application Publication
(10) Pub. No.: US 2016/0147151 A1
(43) Pub. Date: May 26, 2016

(54) RESIST UNDERLAYER FILM-FORMING COMPOSITION CONTANING PYRROLE NOVOLAC RESIN

(71) Applicant: NISSAN CHEMICAL INDUSTRIES, LTD., Tokyo (JP)

(72) Inventors: Tetsuya SHINJO, Toyama-shi (JP); Yasunobu SOMEYA, Toyma-shi (JP); Ryo KARASAWA, Toyama-shi (JP); Hirokazu NISHIMAKI, Toyama-shi (JP); Takafumi ENDO, Toyama-shi (JP); Keisuke HASHIMOTO, Toyama-shi (JP)

(73) Assignee: NISSAN CHEMICAL INDUSTRIES, LTD., Tokyo (JP)

(21) Appl. No.: 14/900,406

(22) PCT Filed: Jun. 23, 2014
(86) PCT No.: PCT/JP2014/066560

§ 371 Date: Dec. 21, 2015

(30) Foreign Application Priority Data
Jun. 25, 2013 (JP) 2013-132873

(51) Int. Cl. G03F 7/11; C08G 12/26; H01L 21/308; G03F 7/20; G03F 7/32; H01L 21/02; C09D 161/26; G03F 7/16

(52) U.S. Cl. CPC G03F 7/11; C09D 161/26; C08G 12/26; G03F 7/16; G03F 7/20; G03F 7/32; H01L 21/02271; H01L 21/3081

(57) ABSTRACT

An excellent resist underlayer film having a selectivity of dry etching rate close to that of a resist, selectivity of dry etching rate lower than that of a resist, or selectivity of dry etching rate lower than that of semiconductor substrate. Resist underlayer film-forming composition including a polymer containing unit structure of Formula (1):

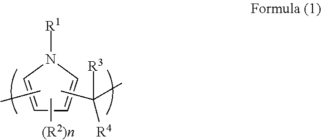

(where R³ is hydrogen atom, or C₆₋₄₀ aryl group or heterocyclic group optionally substituted with halogen group, nitro group, amino group, carbonyl group, C₆₋₄₀ aryl group, or hydroxy group; R⁴ is a hydrogen atom, or C₁₋₁₀ alkyl group, C₆₋₄₀ aryl group, or heterocyclic group optionally substituted with halogen group, nitro group, amino group, or hydroxy group; R³ and R⁴ optionally form ring together with carbon atoms bonded thereto; and n is an integer of 0 to 2).

### TECHNICAL FIELD

The present invention relates to a resist underlayer film-forming composition for lithography that is effective at the time of semiconductor substrate processing, a method for forming a resist pattern using the resist underlayer film-forming composition, and a method for producing a semiconductor device.

### BACKGROUND ART

Conventionally, microfabrication has been carried out by lithography using a photoresist composition in the production of semiconductor devices. The microfabrication is a method for processing which includes: forming a thin film of a photoresist composition on a substrate to be processed such as a silicon wafer; irradiating the thin film with active light such as ultraviolet rays through a mask pattern in which a pattern of a semiconductor device is depicted; developing the pattern; and etching the processed substrate such as a silicon wafer by using the obtained photoresist pattern as a protection film. In recent years, however, semiconductor devices have been further integrated, and the active light to be used has had a shorter wavelength from a KrF excimer laser (248 nm) to an ArF excimer laser (193 nm). This causes serious problems of the effects of diffused reflection of active light from the substrate and standing wave. Consequently, a method for providing a bottom anti-reflective coating (BARC) between a photoresist and a substrate to be processed has been widely applied.

When the formation of the finer resist pattern is progressed in the future, the problem of resolution and the problem of resist pattern collapse after development will occur and thus formation of a thinner resist film will be desired. Consequently, the resist pattern thickness sufficient for substrate processing is difficult to be secured. As a result, not only the resist pattern but also the resist underlayer film formed between the resist and the semiconductor substrate to be processed has been required to have the function as a mask at the time of the substrate processing. As the resist underlayer film for such a process, the resist underlayer film for lithography having the selectivity of dry etching rate close to that of the resist, the resist underlayer film for lithography having the selectivity of dry etching rate lower than that of the resist, or the resist underlayer film for lithography having the selectivity of dry etching rate lower than that of the semiconductor substrate, which is different from conventional high etching rate (etching rate is fast) resist underlayer films, has been required.

As the polymer for the resist underlayer film, the following polymers are exemplified. A resist underlayer film-forming composition using novolac carbazole is exemplified (refer to Patent Document 1, Patent Document 2, and Patent Document 3).

### PRIOR ART DOCUMENTS

### Patent Documents

Patent Document 1: WO 2010/147155 Pamphlet

Patent Document 2: WO 2012/077640 Pamphlet

Patent Document 3: WO 2013/005797 Pamphlet

### SUMMARY OF THE INVENTION

### Problem to be Solved by the Invention

An object of the present invention is to provide a resist underlayer film-forming composition for use in the lithography process of semiconductor device production. Another object of the present invention is to provide the resist underlayer film for lithography having the selectivity of dry etching rate close to that of the resist, the resist underlayer film for lithography having the selectivity of dry etching rate lower than that of the resist, or the resist underlayer film for lithography having the selectivity of dry etching rate lower than that of the semiconductor substrate, which does not cause intermixing with a resist layer and allow excellent resist patterns to be obtained. According to the present invention, a function effectively absorbing reflected light from a substrate at the time of use of irradiation light having wavelength of 248 nm, 193 nm., 157 nm, or the like for microfabrication can be provided. Another object of the present invention is to provide a method for forming a resist pattern using the resist underlayer film-forming composition. Another object of the present invention is to provide a resist underlayer film-forming composition for forming a resist underlayer film also having heat resistance.

### Means for Solving the Problem

The invention in this specification provides, as a first aspect, a resist underlayer film-forming composition comprising a polymer containing a unit structure of Formula (1):

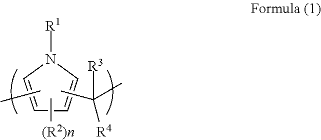

(where R¹ is selected from the group consisting of a hydrogen atom, a C₁₋₁₀ alkyl group, a C₂₋₁₀ alkenyl group, a C₆₋₄₀ aryl group, or a combination thereof, and at this time, the alkyl group, the alkenyl group, or the aryl group optionally contains an ether bond, a ketone bond, or an ester bond; R² is selected from the group consisting of a halogen group, a nitro group, an amino group, a hydroxy group, a C₁₋₁₀ alkyl group, a C₂₋₁₀ alkenyl group, a C₆₋₄₀ aryl group, or a combination thereof, and at this time, the alkyl group, the alkenyl group, or the aryl group optionally contains an ether bond, a ketone bond, or an ester bond; R³ is a hydrogen atom, or a C₆₋₄₀ aryl group or a heterocyclic group optionally substituted with a halogen group, a nitro group, an amino group, a carbonyl group, a C₆₋₄₀ aryl group, or a hydroxy group; R⁴ is a hydrogen atom, or a C₁₋₁₀ alkyl group, a C₆₋₄₀ aryl group, or a heterocyclic group optionally substituted with a halogen group, a nitro group, an amino group, or a hydroxy group; R³ and R⁴ optionally form a ring together with carbon atoms bonded thereto; and n is an integer of 0 to 2),

as a second aspect, the resist underlayer film-forming composition as described in the first aspect, in which in Formula (1), R³ is a benzene ring, a naphthalene ring, an anthracene ring, or a pyrene ring; R⁴ is a hydrogen atom; and n is 0,

as a third aspect, the resist underlayer film-forming composition as described in the first aspect or the second aspect, further comprising a crosslinking agent,

as a fourth aspect, the resist underlayer film-forming composition as described in any one of the first aspect to the third aspect, further comprising an acid and/or an acid generator,

as a fifth aspect, a resist underlayer film obtained by applying the resist underlayer film-forming composition as described in any one of the first aspect to the fourth aspect onto a semiconductor substrate and baking the applied resist underlayer film-forming composition,

as a sixth aspect, a method for forming a resist pattern for use in semiconductor production, the method comprising the step of: forming an underlayer film by applying the resist underlayer film-forming composition as described in any one of the first aspect to the fourth aspect onto a semiconductor substrate and baking the applied resist underlayer film-forming composition,

as a seventh aspect, a method for producing a semiconductor device, the method comprising the steps of: forming an underlayer film from the resist underlayer film-forming composition as described in any one of the first aspect to the fourth aspect onto a semiconductor substrate; forming a resist film on the underlayer film; forming a resist pattern by irradiation with light or an electron beam and development; etching the underlayer film by using the resist pattern; and processing the semiconductor substrate by using the patterned underlayer film,

as an eighth aspect, a method for producing a semiconductor device, the method comprising the steps of: forming an underlayer film from the resist underlayer film-forming composition as described in any one of the first aspect to the fourth aspect onto a semiconductor substrate; forming a hard mask on the underlayer film; forming a resist film on the hard mask; forming a resist pattern by irradiation with light or an electron beam and development; etching the hard mask by using the resist pattern; etching the underlayer film by using the patterned hard mask; and processing the semiconductor substrate by using the patterned underlayer film,

as a ninth aspect, the method for producing a semiconductor device as described in the eighth aspect, in which the hard mask is formed by vapor deposition of an inorganic substance, and

as a tenth aspect, a polymer containing a unit structure of Formula (5):

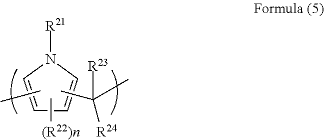

(where R²¹ is selected from the group consisting of a hydrogen atom, a C₁₋₁₀ alkyl group, a C₂₋₁₀ alkenyl group, a C₆₋₄₀ aryl group, or a combination thereof, and at this time, the alkyl group, the alkenyl group, or the aryl group optionally contains an ether bond, a ketone bond, or an ester bond; R²² is selected from the group consisting of a halogen group, a nitro group, an amino group, a hydroxy group, a C₁₋₁₀ alkyl group, a C₂₋₁₀ alkenyl group, a C₆₋₄₀ aryl group, or a combination thereof, and at this time, the alkyl group, the alkenyl group, or the aryl group optionally contains an ether bond, a ketone bond, or an ester bond; R²³ is a hydrogen atom, or a C₆₋₄₀ aryl group or a heterocyclic group optionally substituted with a halogen group, a nitro group, an amino group, a carbonyl group, a C₆₋₄₀ aryl group, or a hydroxy group; R²⁴ is a C₁₋₁₀ alkyl group, a C₆₋₄₀ aryl group, or a heterocyclic group optionally substituted with a halogen group, a nitro group, an amino group, or a hydroxy group; R²³ and R²⁴ optionally form a ring together with carbon atoms bonded thereto; and n is an integer of 0 to 2).

### Effects of the Invention

Use of the resist underlayer film-forming composition of the present invention eliminates intermixing of the upper part of the resist underlayer film with a layer covering the resist underlayer film and allows the excellent pattern shapes of the resist film to be formed.

A function that effectively reduces reflection from the substrate can be provided for the resist underlayer film-forming composition of the present invention and thus the resist underlayer film also has an effect as an anti-reflective coating to exposed light.

Use of the resist underlayer film-forming composition of the present invention can provide the excellent resist underlayer film for lithography having the selectivity of dry etching rate close to that of the resist, the selectivity of dry etching rate lower than that of the resist, or the selectivity of dry etching rate lower than that of the semiconductor substrate.

In association with finer resist pattern formation, a thinner resist film is formed in order to prevent resist pattern collapse after development. For such a thin film resist, a process of transferring a resist pattern to the underlayer film of the resist by an etching process; and processing a substrate using the underlayer film as a mask, or a process of transferring a resist pattern to the underlayer film of the resist by an etching process; further transferring the pattern transferred to the underlayer film to the underlayer film of the pattern-transferred underlayer film using a different gas composition; repeating these processes; and finally processing the substrate is used. The resist underlayer film and the forming composition thereof of the present invention are effective for these processes and have sufficient etching resistance to the processing substrate (for example, a thermally oxidized silicon film, a silicon nitride film, and a polysilicon film on the substrate) at the time of processing the substrate using the resist underlayer films of the present invention.

The resist underlayer film for the present invention can be used for a planarizing film, a resist underlayer film, a film for preventing contamination to the resist film layer, and a film having a dry etching selectivity. This allows the resist pattern formation in the lithography process of the semiconductor production to be easily and accurately carried out.

The processes of forming a resist underlayer film from the resist underlayer film-forming composition of the present invention onto a substrate; forming a hard mask on the resist underlayer film; forming a resist film on the hard mask; forming a resist pattern by light exposure and development; transferring the resist pattern to the hard mask; transferring the resist pattern transferred to the hard mask to the resist underlayer film; and processing the semiconductor substrate by using the pattern-transferred underlayer film can be applied. The hard mask in this process is formed by an application type composition containing an organic polymer or an inorganic polymer and a solvent or formed by vapor deposition of an inorganic substance. In the vapor deposition of an inorganic substance (for example, silicon nitride oxide), deposited substance is deposited on the surface of the resist underlayer film. At this time, the temperature of the of the resist underlayer film surface rises to around 400° C. In the present invention, the polymer to be used is a polymer containing a pyrrole novolac-based unit structure and thus has extremely high heat resistance and does not cause thermal deterioration by the deposition of the deposited substance.

### MODES FOR CARRYING OUT THE INVENTION

The present invention provides a resist underlayer film-forming composition containing a polymer containing the unit structure of Formula (1). The polymer containing the unit structure of Formula (1) is a novolac polymer prepared by reacting pyrrole with aldehyde or ketone.

In the present invention, the resist underlayer film-forming composition for lithography contains the polymer and a solvent. The underlayer film-forming composition can contain a crosslinking agent and an acid, and optionally contains additives such as an acid generator, a surfactant, or the like. The solid content of the composition is 0.1% by mass to 70% by mass or 0.1% by mass to 60% by mass. The solid content is a content ratio of the whole components of the resist underlayer film-forming composition from which the solvent is removed. In the solid content, the polymer can be contained in a ratio of 1% by mass to 100% by mass, 1% by mass to 99.9% by mass, 50% by mass to 99.9% by mass, 50% by mass to 95% by mass, or 50% by mass to 90% by mass.

The polymer used in the present invention has a weight average molecular weight of 600 to 1,000,000 or 600 to 200,000.

In Formula (1), R¹ is selected from the group consisting of a hydrogen atom, a C₁₋₁₀ alkyl group, a C₂₋₁₀ alkenyl group, a C₆₋₄₀ aryl group, or a combination thereof, and at this time, the alkyl group, the alkenyl group, or the aryl group optionally contains an ether bond, a ketone bond, or an ester bond. R² is selected from the group consisting of a halogen group, a nitro group, an amino group, a hydroxy group, a C₁₋₁₀ alkyl group, a C₂₋₁₀ alkenyl group, a C₆₋₄₀ aryl group, or a combination thereof, and at this time, the alkyl group, the alkenyl group, or the aryl group optionally contains an ether bond, a ketone bond, or an ester bond. R³ is a hydrogen atom, or a C₆₋₄₀ aryl group or a heterocyclic group optionally substituted with a halogen group, a nitro group, an amino group, a carbonyl group, a C₄₋₄₀ aryl group, or a hydroxy group; R⁴ is a hydrogen atom, or a C₁₋₁₀ alkyl group, a C₆₋₄₀ aryl group, or a heterocyclic group optionally substituted with a halogen group, a nitro group, an amino group, or a hydroxy group; and R³ and R⁴ optionally form a ring together with carbon atoms bonded thereto. These rings, for example, can have a structure in which R³ and R⁴ each are bonded to the 9 position of fluorene. n is an integer of 0 to 2.

R³ in Formula (1) can be a benzene ring, a naphthalene ring, an anthracene ring, or a pyrene ring; R⁴ can be a hydrogen atom; and n can be 0.

Examples of the halogen group may include a fluorine atom, a chlorine atom, a bromine atom, and an iodine atom.

Examples of the C₆₋₄₀ aryl group may include, when the C₆₋₄₀ aryl group is a phenyl group and the C₆₋₄₀ aryl group optionally substituted is a phenyl group, a phenyl group substituted with a phenyl group (that is, a biphenyl group).

Examples of the C₁₋₁₀ alkyl group may include methyl, ethyl, n-propyl, i-propyl, cyclopropyl, n-butyl, i-butyl, s-butyl, t-butyl, cyclobutyl, 1-methyl-cyclopropyl, 2-methyl-cyclopropyl, n-pentyl, 1-methyl-n-butyl, 2-methyl-n-butyl, 3-methyl-n-butyl, 1,1-dimethyl-n-propyl, 1,2-dimethyl-n-propyl, 2,2-dimethyl-n-propyl, 1-ethyl-n-propyl, cyclopentyl, 1-methyl-cyclobutyl, 2-methyl-cyclobutyl, 3-methyl-cyclobutyl, 1,2-dimethyl-cyclopropyl, 2,3-dimethyl-cyclopropyl, 1-ethyl-cyclopropyl, 2-ethyl-cyclopropyl, n-hexyl, 1-methyl-n-pentyl, 2-methyl-n-pentyl, 3-methyl-n-pentyl, 4-methyl-n-pentyl, 1,1-dimethyl-n-butyl, 1,2-dimethyl-n-butyl, 1,3-dimethyl-n-butyl, 2,2-dimethyl-n-butyl, 2,3-dimethyl-n-butyl, 3,3-dimethyl-n-butyl, 1-ethyl-n-butyl, 2-ethyl-n-butyl, 1,1,2-trimethyl-n-propyl, 1,2,2-trimethyl-n-propyl, 1-ethyl-1-methyl-n-propyl, l-ethyl-2-methyl-n-propyl, cyclohexyl, 1-methyl-cyclopentyl, 2-methyl-cyclopentyl, 3-methyl-cyclopentyl, 1-ethyl-cyclobutyl, 2-ethyl-cyclobutyl, 3-ethyl-cyclobutyl, 1,2-dimethyl-cyclobutyl, 1,3-dimethyl-cyclobutyl, 2,2-dimethyl-cyclobutyl, 2,3-dimethyl-cyclobutyl, 2,4-dimethyl-cyclobutyl, 3,3-dimethyl-cyclobutyl, l-n-propyl-cyclopropyl, 2-n-propyl-cyclopropyl, 1-i-propyl-cyclopropyl, 2-i-propyl-cyclopropyl, 1,2,2-trimethyl-cyclopropyl, 1,2,3-trimethyl-cyclopropyl, 2,2,3-trimethyl-cyclopropyl, 1-ethyl-2-methyl-cyclopropyl, 2-ethyl-1-methyl-cyclopropyl, 2-ethyl-2-methyl-cyclopropyl, and 2-ethyl-3-methyl-cyclopropyl.

Examples of the C₂₋₁₀ alkenyl group may include ethenyl, 1-propenyl, 2-propenyl, 1-methyl-1-ethenyl, 1-butenyl, 2-butenyl, 3-butenyl, 2-methyl-1-propenyl, 2-methyl-2-propenyl, 1-ethylethenyl, 1-methyl-1-propenyl, 1-methyl-2-propenyl, 1-pentenyl, 2-pentenyl, 3-pentenyl, 4-pentenyl, 1-n-propylethenyl, 1-methyl-1-butenyl, 1-methyl-2-butenyl, 1-methyl-3-butenyl, 2-ethyl-2-propenyl, 2-methyl-1-butenyl, 2-methyl-2-butenyl, 2-methyl-3-butenyl, 3-methyl-1-butenyl, 3-methyl-2-butenyl, 3-methyl-3-butenyl, 1,1-dimethyl-2-propenyl, 1-i-propylethenyl, 1,2-dimethyl-1-propenyl, 1,2-dimethyl-2-propenyl, 1-cyclopentenyl, 2-cyclopentenyl, 3-cyclopentenyl, 1-hexenyl, 2-hexenyl, 3-hexenyl, 4-hexenyl, 5-hexenyl, 1-methyl-1-pentenyl, 1-methyl-2-pentenyl, 1-methyl-3-pentenyl, 1-methyl-4-pentenyl, 1-n-butylethenyl, 2-methyl-1-pentenyl, 2-methyl-2-pentenyl, 2-methyl-3-pentenyl, 2-methyl-4-pentenyl, 2-n-propyl-2-propenyl, 3-methyl-1-pentenyl, 3-methyl-2-pentenyl, 3-methyl-3-pentenyl, 3-methyl-4-pentenyl, 3-ethyl-3-butenyl, 4-methyl-1-pentenyl, 4-methyl-2-pentenyl, 4-methyl-3-pentenyl, 4-methyl-4-pentenyl, 1,1-dimethyl-2-butenyl, 1,1-dimethyl-3-butenyl, 1,2-dimethyl-1-butenyl, 1,2-dimethyl-2-butenyl, 1,2-dimethyl-3-butenyl, 1-methyl-2-ethyl-2-propenyl, 1-s-butylethenyl, 1,3-dimethyl-1-butenyl, 1,3-dimethyl-2-butenyl, 1,3-dimethyl-3-butenyl, 1-i-butylethenyl, 2,2-dimethyl-3-butenyl, 2,3-dimethyl-1-butenyl, 2,3-dimethyl-2-butenyl, 2,3-dimethyl-3-butenyl, 2-i-propyl-2-propenyl, 3,3-dimethyl-1-butenyl, 1-ethyl-1-butenyl, l-ethyl-2-butenyl, 1-ethyl-3-butenyl, 1-n-propyl-1-propenyl, 1-n-propyl-2-propenyl, 2-ethyl-1-butenyl, 2-ethyl-2-butenyl, 2-ethyl-3-butenyl, 1,1,2-trimethyl-2-propenyl, 1-t-butylethenyl, 1-methyl-1-ethyl-2-propenyl, 1-ethyl-2-methyl-1-propenyl, 1-ethyl-2-methyl-2-propenyl, 1-i-propyl-1-propenyl, 1-i-propyl-2-propenyl, 1-methyl-2-cyclopentenyl, 1-methyl-3-cyclopentenyl, 2-methyl-1-cyclopentenyl, 2-methyl-2-cyclopentenyl, 2-methyl-3-cyclopentenyl, 2-methyl-4-cyclopentenyl, 2-methyl-5-cyclopentenyl, 2-methylene-cyclopentyl, 3-methyl-1-cyclopentenyl, 3-methyl-2-cyclopentenyl, 3-methyl-3-cyclopentenyl, 3-methyl-4-cyclopentenyl, 3-methyl-5-cyclopentenyl, 3-methylene-cyclopentyl, 1-cyclohexenyl, 2-cyclohexenyl, and 3-cyclohexenyl.

Examples of C₆₋₄₀ aryl group may include phenyl group, o-methylphenyl group, m-methylphenyl group, p-methylphenyl group, o-chlorophenyl group, m-chlorophenyl group, p-chlorophenyl group, o-fluorophenyl group, p-fluorophenyl group, o-methoxyphenyl group, p-methoxyphenyl group, p-nitrophenyl group, p-cyanophenyl group, α-naphthyl group, β-naphthyl group, o-biphenylyl group, m-biphenylyl group, p-biphenylyl group, l-anthryl group, 2-anthryl group, 9-anthryl group, 1-phenanthryl group, 2-phenanthryl group, 3-phenanthryl group, 4-phenanthryl group, and 9-phenanthryl group.

As the heterocyclic group, an organic group made of a 5- to 6-membered heterocycle containing nitrogen, sulfur, or oxygen is preferable. Examples of the heterocyclic group may include pyrrole group, furan group, thiophene group, imidazole group, oxazole group, thiazole group, pyrazole group, isoxazole group, isothiazole group, and pyridine group.

Examples of the aldehyde for use in polymer production of the present invention may include saturated aliphatic aldehydes such as formaldehyde, paraformaldehyde, acetaldehyde, propylaldehyde, butyraldehyde, isobutyraldehyde, valeraldehyde, capronaldehyde, 2-methylbutyraldehyde, hexylaldehyde, undecanaldehyde, 7-methoxy-3,7-dimethyloctylaldehyde, cyclohexanealdehyde, 3-methyl-2-butyraldehyde, glyoxal, malonaldehyde, succinaldehyde, glutaraldehyde, and adipaldehyde, unsaturated aliphatic aldehydes such as acrolein and methacrolein, heterocyclic aldehydes such as furfural and pyridinealdehyde, and aromatic aldehydes such as benzaldehyde, naphthylaldehyde, anthrylaldehyde, phenanthrylaldehyde, salicylaldehyde, phenylacetaldehyde, 3-phenylpropionaldehyde, tolylaldehyde, (N,N-dimethylamino)benzaldehyde, and acetoxybenzaldehyde. In particular, the aromatic aldehydes can be preferably used.

As the ketones for use in polymer production of the present invention, diaryl ketones are used. Example of the diaryl ketones may include diphenyl ketone, phenyl naphthyl ketone, dinaphthyl ketone, phenyl tolyl ketone, ditolyl ketone, and 9-fluorenone.

The polymer used in the present invention is a novolac resin obtained by condensing pyrrole and the aldehydes or the ketones. In this condensation reaction, the aldehydes or the ketones are used in a ratio of 0.1 equivalent to 10 equivalent relative to 1 equivalent of pyrrole.

Examples of the usable acid catalyst used in the condensation reaction may include mineral acids such as sulfuric acid, phosphoric acid, and perchloric acid; organic sulfonic acids such as p-toluenesulfonic acid, and p-toluenesulfonic acid monohydrate; and carboxylic acids such as formic acid and oxalic acid. The amount of the acid catalyst to be used is selected depending on the type of the acid catalyst to be used. The amount is usually 0.001 parts by mass to 10,000 parts by mass, preferably 0.01 parts by mass to 1,000 parts by mass, and more preferably 0.1 parts by mass to 100 parts by mass relative to 100 parts by mass of the pyrrole.

The condensation reaction may be carried out without solvent. The condensation reaction is, however, usually carried out with solvent. All of the solvents can be used as long as the solvents do not inhibit the reaction. Examples of the solvent may include ring ethers such as tetrahydrofuran and dioxane. When the acid catalyst to be used is a liquid acid such as formic acid, the acid can also act as a solvent. The reaction temperature at the time of condensation is usually 40° C. to 200° C. The reaction time is variously selected depending on the reaction temperature and usually about 30 minutes to about 50 hours.

The average molecular weight Mw of thus obtained polymer is usually 400 to 1,000,000, 400 to 200,000, 400 to 50,000, or 600 to 10,000.

The polymer containing the unit structure of Formula (1) can be exemplified as follows:

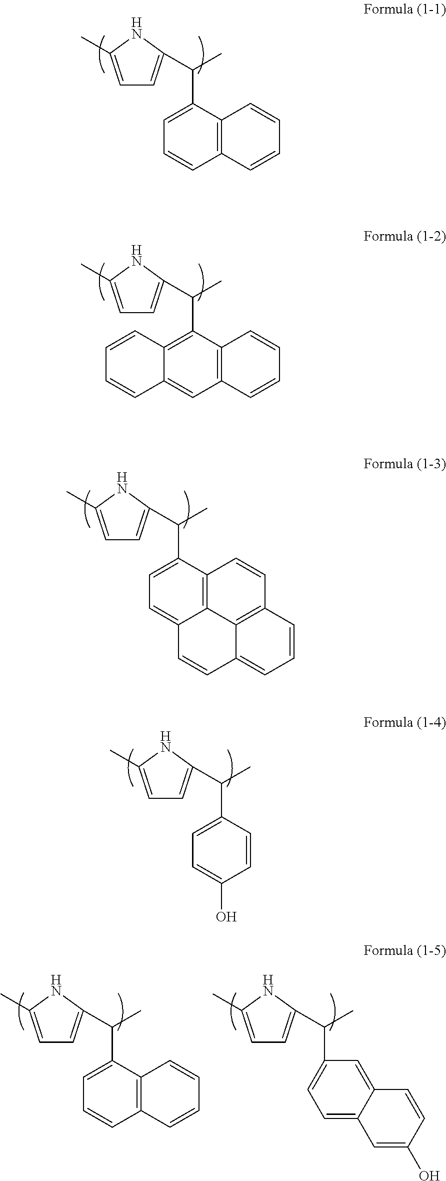

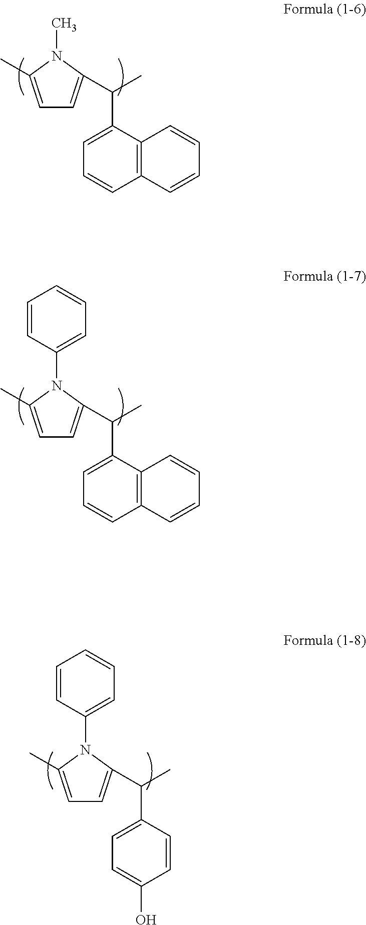

The polymer can be used by mixing with other polymers within 30% by mass to the total polymers.

Examples of the polymers may include polyacrylate compounds, polymethacrylate compounds, polyacrylamide compounds, polymethacrylamide compounds, polyvinyl compounds, polystyrene compounds, polymaleimide compound, polymaleic anhydrides, and polyacrylonitrile compounds.

Examples of the raw material monomer of the polyacrylate compounds may include methyl acrylate, ethyl acrylate, isopropyl acrylate, benzyl acrylate, naphthyl acrylate, anthryl acrylate, anthrylmethyl acrylate, phenyl acrylate, 2-hydroxyethyl acrylate, 2-hydroxypropyl acrylate, 2,2,2-trifluoroethyl acylate, 4-hydroxybutyl acrylate, isobutyl acrylate, tert-butyl acrylate, cyclohexyl acrylate, isobornyl acrylate, 2-methoxyethyl acrylate, methoxy triethylene glycol acrylate, 2-ethoxyethyl acrylate, tetrahydrofurfuryl acrylate, 3-methoxybutyl acrylate, 2-methyl-2-adamantyl acrylate, 2-ethyl-2-adamantyl acrylate, 2-propyl 2-adamantyl acrylate, 2-methoxybutyl-2-adamantyl acrylate, 8-methyl-8-tricyclodecyl acrylate, 8-ethyl-8-tricyclodecyl acrylate, and 5-acryloyloxy-6-hydroxynorbornan-2-carboxylic-6-lactone.

Examples of the raw material monomer of the polymethacrylate compounds may include ethyl methacrylate, normal-propyl methacrylate, normal-pentyl methacrylate, cyclohexyl methacrylate, benzyl methacrylate, naphthyl methacrylate, anthryl methacrylate, anthrylmethyl methacrylate, phenyl methacrylate, 2-phenylethyl methacrylate, 2-hydroxyethyl methacrylate, 2-hydroxypropyl methacrylate, 2,2,2-trifluoroethyl methacrylate, 2,2,2-trichloroethyl methacrylate, methyl methacrylate, isobutyl methacrylate, 2-ethylhexyl methacrylate, isodecyl methacrylate, normal-lauryl methacrylate, normal-stearyl methacrylate, methoxy diethylene glycol methacrylate, methoxy polyethylene glycol methacrylate, tetrahydrofurfuryl methacrylate, isobornyl methacrylate, tert-butyl methacrylate, isostearyl methacrylate, normal-butoxyethyl methacrylate, 3-chloro-2-hydroxypropyl methacrylate, 2-methyl-2-adamantyl methacrylate, 2-ethyl-2-adamantyl methacrylate, 2-propyl-2-adamantyl methacrylate, 2-methoxybutyl-2-adamantyl methacrylate, 8-methyl-8-tricyclodecyl methacrylate, 8-ethyl-8-tricyclodecyl methacrylate, 5-methacryloyloxy-6-hydroxynobornene-2-carboxylic-6-lactone, and 2,2,3,3,4,4,4-heptafluorobutyl methacrylate.

Examples of the raw material monomer of the polyacrylamide compounds may include acrylamide, N-methylacrylamide, N-ethylacrylamide, N-benzylacrylamide, N-phenylacrylamide, and N,N-dimethylacrylamide.

Examples of the raw material monomer of the polymethacrylamide compounds may include methacrylamide, N-methylmethacrylamide, N-ethylmethyacrylamide, N-benzylmethacrylamide, N-phenylmethacrylamide, and N,N-dimethylmethacrylamide.

Examples of the raw material monomer of the polyvinyl compounds may include, vinyl ether, methyl vinyl ether, benzyl vinyl ether, 2-hydroxyethyl vinyl ether, phenyl vinyl ether, and propyl vinyl ether.

Examples of the raw material monomer of the polystyrene compounds may include styrene, methylstyrene, chlorostyrene, bromostyrene, and hydroxystyrene.

Examples of the raw material monomer of the polymaleimide compounds may include maleimide, N-methylmaleimide, N-phenylmaleimide, and N-cyclohexylmaleimide.

These polymers can be produced by dissolving the addition-polymerizable monomer, and chain transfer agent (10% or less relative to the mass of the monomer) added if necessary, in an organic solvent, thereafter carrying out polymerization reaction by adding a polymerization initiator, and then adding a polymerization terminator. The amount of the polymerization initiator to be added is 1% by mass to 10% by mass and the amount of the polymerization terminator is 0.01% by mass to 0.2% by mass relative to the mass of the monomer. Examples of the organic solvent to be used may include propylene glycol monomethyl ether, propylene glycol monopropyl ether, ethyl lactate, cyclohexanone, methyl ethyl ketone, and dimethyl formamide. Examples of the chain transfer agent may include dodecanethiol and dodecylthiol. Examples of the polymerization initiator may include azobis-isobutyronitrile and azobis-cyclohexanecarbonitrile. Examples of the polymerization terminator may include 4-methoxyphenol. The reaction temperature is appropriately selected from 30° C. to 100° C. and the reaction time is appropriately selected from 1 hour to 48 hours.

The resist underlayer film-forming composition of the present invention may include a crosslinking agent component. Examples of the crosslinking agent may include a melamine-based agent, a substituted urea-based agent, or a polymer-based agent thereof. Preferably, the crosslinking agent has at least two crosslink-forming substituents. Examples of the crosslinking agent may include compounds such as methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea, or methoxymethylated thiourea. A condensate of these compounds can also be used.

As the crosslinking agent, a crosslinking agent having high heat resistance can be used. As the crosslinking agent having high heat resistance, a compound containing a crosslink-forming substituent having an aromatic ring (for example, a benzene ring or a naphthalene ring) in its molecule can preferably be used.

Examples of the compound may include a compound having a partial structure of Formula (2) and a polymer or an oligomer having a repeating unit of Formula (3).

In Formula (2), R¹⁰ and R¹¹ each are a hydrogen atom, a C₁₋₁₀ alkyl group, or C₆₋₂₀ aryl group; n10 is an integer of 1 to 4; n11 is an integer of 1 to (5-n10); and (n10+n11) is an integer of 2 to 5.

In Formula (3), R¹² is a hydrogen atom or a C₁₋₁₀ alkyl group; R¹³ is a C₁₋₁₀ alkyl group; n12 is an integer of 1 to 4; n13 is an integer of 0 to (4-n12); and (n12+n13) is an integer of 1 to 4. The oligomer and the polymer can be used in a range of the number of the repeating unit structure of 2 to 100 or in a range of 2 to 50.

As these alkyl group and aryl group, the alkyl group and the aryl group described above can be exemplified.

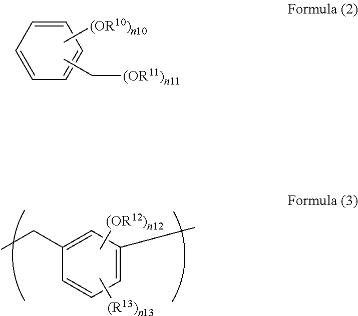

The compounds, the polymers, and the oligomers of Formula (2) and Formula (3) are exemplified as follows:

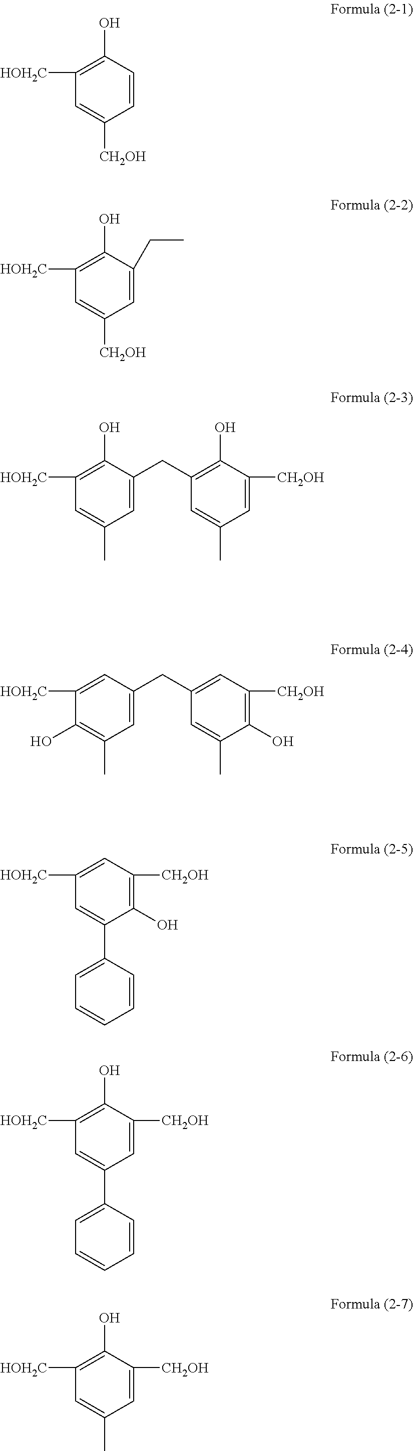

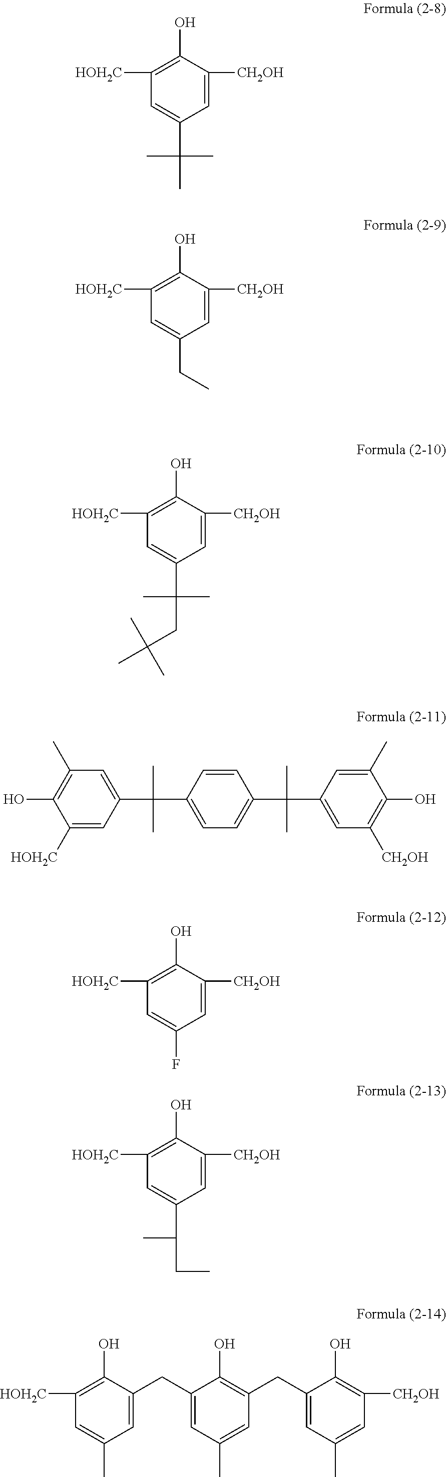

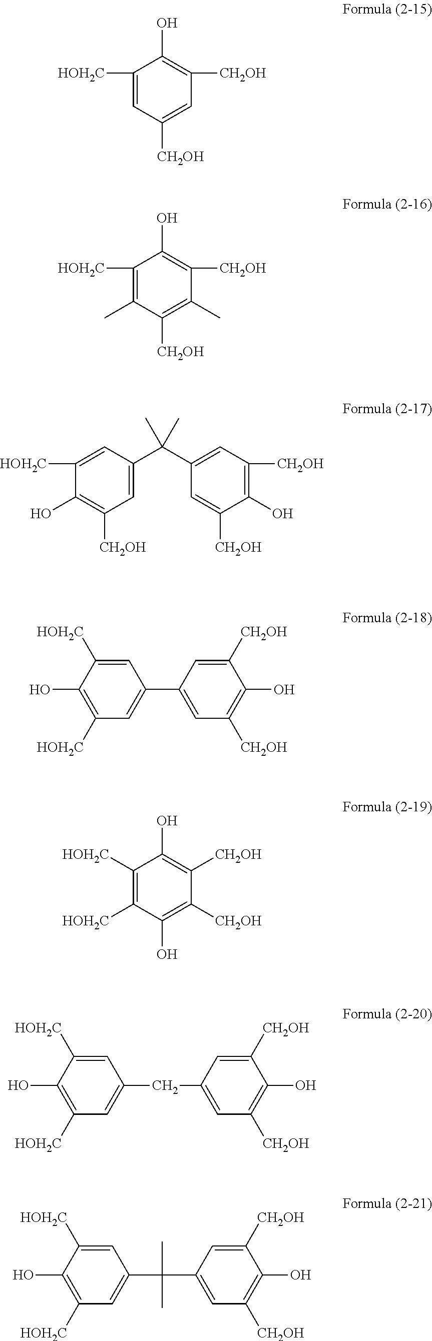

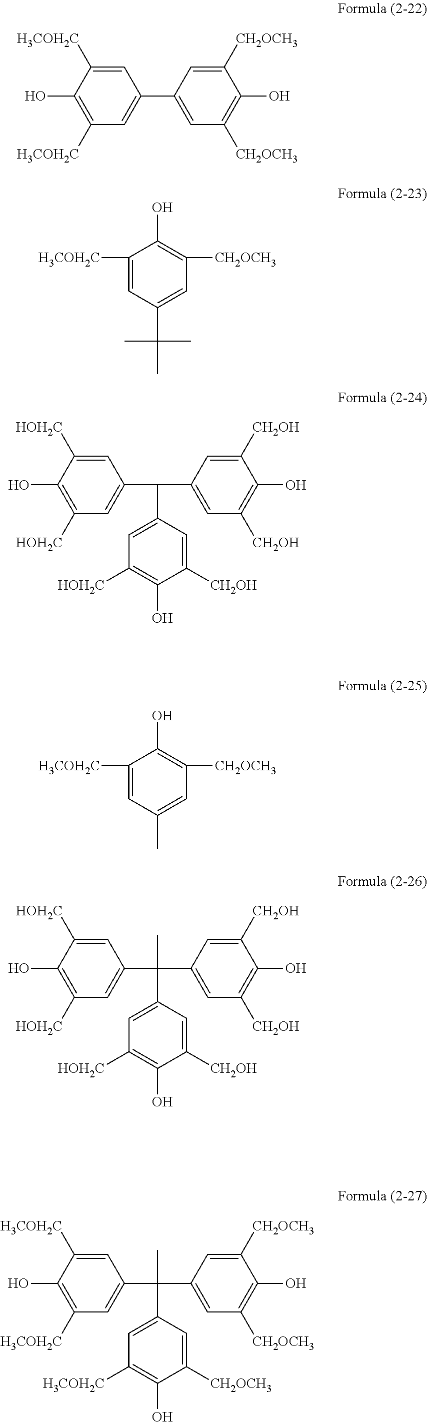

The compounds can be obtained as commercial products manufactured by Asahi Organic Chemicals Industry Co., Ltd. or HONSHU CHEMICAL INDUSTRY CO., LTD. For example, among the crosslinking agent, the compound of Formula (2-21) can be obtained as TM-RIP-A (trade name, manufactured by Asahi Organic Chemicals Industry Co., Ltd.) and the compound of Formula (2-22) can be obtained as TMOM-BP (trade name, HONSHU CHEMICAL INDUSTRY CO., LTD.).

An amount of the crosslinking agent to be added varies depending on an application solvent used, a base substrate used, a required solution viscosity, a required film shape, and the like. The amount is 0.001% by mass to 80% by mass, preferably 0.01% by mass to 50% by mass, and further preferably 0.05% by mass to 40% by mass relative to the whole solid content. These crosslinking agents may cause a crosslinking reaction by self-condensation. The crosslinking agent can, however, cause a crosslinking reaction with a crosslinkable substituent when the crosslinkable substituent exists in the polymer of the present invention.

In the present invention, acidic compounds such as p-toluenesulfonic acid, trifluoromethanesulfonic acid, pyridinium p-toluenesulfonate, salicylic acid, sulfosalicylic acid, citric acid, benzoic acid, hydroxybenzoic acid, naphthalene carboxylic acid and/or thermal acid generators such as 2,4,4,6-tetrabromocyclohexadienone, benzoin tosylate, 2-nitrobenzyl tosylate, and other organic sulfonic acid alkyl ester can be added as a catalyst for promoting the crosslinking reaction. The amount of the catalyst to be added is 0.0001% by mass to 20% by mass, preferably 0.0005% by mass to 10% by mass, and more preferably 0.01% by mass to 3% by mass relative to the whole solid content.

In order to match the acidity of the application type underlayer film-forming composition for lithography of the present invention to the acidity of the photoresist that covers the upper part of the resist underlayer film in the lithography process, a photoacid generator can be added to the application type underlayer film-forming composition for lithography of the present invention. Examples of the preferable photoacid generator may include an onium salt photoacid generators such as bis(4-t-butylphenyl)iodonium trifluoromethanesulfonate and triphenylsulfonium trifluoromethanesulfonate; halogen-containing compound photoacid generators such as phenyl-bis(trichloromethyl)-s-triazine; and sulfonic acid photoacid generators such as benzoin tosylate and N-hydroxysuccinimide trifluoromethanesulfonate. The amount of the photoacid generator is 0.2% by mass to 10% by mass and preferably 0.4% by mass to 5% by mass relative to the whole solid content.

To the resist underlayer film material for lithography of the present invention, for example, a further light absorbent, a rheology modifier, an adhesion assistance agent, or a surfactant can be added in addition to the components described above if necessary.

As further light absorbents, for example, commercially available light absorbents described in “Kogyoyo Shikiso no Gijutu to Shijyo (Technology and Market of Industrial Colorant)” (CMC Publishing Co., Ltd) and “Senryo Binran (Dye Handbook)” (The Society of Synthetic Organic Chemistry, Japan) can be preferably used. Preferably useable examples of the commercially available light absorbents include C. I. Disperse Yellow 1, 3, 4, 5, 7, 8, 13, 23, 31, 49, 50, 51, 54, 60, 64, 66, 68, 79, 82, 88, 90, 93, 102, 114, and 124; C. I. Disperse Orange 1, 5, 13, 25, 29, 30, 31, 44, 57, 72, and 73; C. I. Disperse Red 1, 5, 7, 13, 17, 19, 43, 50, 54, 58, 65, 72, 73, 88, 117, 137, 143, 199, and 210; C. I. Disperse Violet 43; C. I. Disperse Blue 96; C. I. Fluorescent Brightening Agent 112, 135, and 163; C. I. Solvent Orange 2 and 45; C. I. Solvent Red 1, 3, 8, 23, 24, 25, 27, and 49; C. I. Pigment Green 10; and C. I. Pigment Brown 2. The light absorbents are usually added in a ratio of 10% by mass or less, and preferably in a ratio of 5% by mass or less relative to the whole solid content of the resist underlayer film material for lithography.

The rheology modifier is added for the purpose of mainly improving flowability of the resist underlayer film-forming composition, and, particularly in a baking process, improving film thickness uniformity of the resist underlayer film and enhancing filling ability of the resist underlayer film-forming composition into the inside of a hole. Specific examples of the rheology modifier may include phthalic acid derivatives such as dimethyl phthalate, diethyl phthalate, diisobutyl phthalate, dihexyl phthalate, and butylisodecyl phthalate, adipic acid derivatives such as di-normal-butyl adipate, diisobutyl adipate, diisooctyl adipate, and octyldecyl adipate, maleic acid derivatives such as di-normal-butylmaleate, diethyl maleate, and dinonyl maleate, oleic acid derivatives such as methyl oleate, butyl oleate, and tetrahydrofurfuryl oleate, or stearic acid derivatives such as normal-butyl stearate, and glyceryl stearate. These rheology modifiers are usually added in a ratio of less than 30% by mass relative to the whole solid content of the resist underlayer film material for lithography.

The adhesion assistance agent is mainly added so that adhesion between the substrate or the resist and the resist underlayer film-forming composition is improved and that the resist is not peeled, particularly in development. Specific examples of the adhesion assistance agent may include chlorosilanes such as trimethylchlorosilane, dimethylvinylchlorosilane, methyldiphenylchlorosilane, and chloromethyldimethylchlorosilane, alkoxysilanes such as trimethylmethoxysilane, dimethyldiethoxysilane, methyldimethoxysilane, dimethylvinylethoxysilane, diphenyldimethoxysilane, and phenyltriethoxysilane, silazanes such as hexamethyldisilazane, N,N′-bis(trimethylsilyl)urea, dimethyltrimethylsilylamine, and trimethylsilylimidazole, silanes such as vinyltrichlorosilane, γ-chloropropyltrimethoxysilane, γ-aminopropyltriethoxysilane, and γ-glycidoxypropyltrimethoxysilane, heterocyclic compounds such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine, and urea compounds or thiourea compounds such as 1,1-dimethylurea and 1,3-dimethylurea. These adhesion assistance agents are usually added in a ratio less than 5% by mass, and preferably in a ratio of less than 2% by mass relative to the whole solid content of the resist underlayer film material for lithography.

To the resist underlayer film material for lithography of the present invention, a surfactant can be added for preventing generation of pinholes and striations and further improving applicability to surface unevenness. Examples of the surfactant may include nonionic surfactant such as polyoxyethylene alkyl ethers including polyoxyethylene lauryl ether, polyoxyethylene stearyl ether, polyoxyethylene cetyl ether, and polyoxyethylene oleyl ether; polyoxyethylene alkylallyl ethers including polyoxyethylene octylphenol ether and polyoxyethylene nonylphenol ether, polyoxyethylene-polyoxypropylene block copolymers; sorbitan fatty acid esters including sorbitan monolaurate, sorbitan monopalmitate, sorbitan monostearate, sorbitan monooleate, sorbitan trioleate, and sorbitan tristearate; and polyoxyethylene sorbitan fatty acid esters including polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorochemical surfactants such as EFTOP EF301, EF303, and EF352 (manufactured by Tochem Products, trade name), MEGAFAC F171, F173, and R-30 (manufactured by Dainippon Ink and Chemicals Inc., trade name), Fluorad FC430 and FC431 (manufactured by Sumitomo 3M Ltd., trade name), Asahi guard AG710, Surflon S-382, SC101, SC102, SC103, SC104, SC105, and SC106 (manufactured by Asahi Glass Co., Ltd., trade name); and Organosiloxane Polymer KP341 (manufactured by Shin-Etsu Chemical Co., Ltd.). The amount of the surfactant to be added is usually 2.0% by mass or less and preferably 1.0% by mass or less relative to the whole solid content of the resist underlayer film material for lithography of the present invention. These surfactants can be added singly or in combination of two or more of them.

In the present invention, usable examples of a solvent dissolving the polymer, the crosslinking agent component, the crosslinking catalyst, and the like may include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monomethyl ether acetate, propylene glycol monoethyl ether, propylene glycol monoethyl ether acetate, propylene glycol propyl ether acetate, toluene, xylene, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, methyl 3-ethoxypropionate, ethyl 3-ethoxypropionate, methyl pyruvate, ethyl pyruvate, ethyl acetate, butyl acetate, ethyl lactate, and butyl lactate. These solvents can be used singly or in combination of two or more of them.

In addition, these solvents can be used by mixing with a high boiling point solvent such as propylene glycol monobutyl ether and propylene glycol monobutyl ether acetate. Among these solvents, propylene glycol monomethyl ether, propylene glycol monomethyl ether acetate, ethyl lactate, butyl lactate, and cyclohexanone are preferable for improving a levering property.

The resist used in the present invention is a photoresist or an electron beam resist.

As the photoresist applied onto the resist underlayer film for lithography of the present invention, both negative photoresist and positive photoresist can be used. Examples of the resists include a positive photoresist made of a novolac resin and 1,2-naphthoquinonediazidesulfonate, a chemically amplified photoresist made of a binder having a group that increases an alkali dissolution rate by decomposing with an acid and a photoacid generator, a chemically amplified photoresist made of an alkali-soluble binder, a low molecular weight compound that increases an alkali dissolution rate of the photoresist by decomposing with an acid, and a photoacid generator, a chemically amplified photoresist made of a binder having a group that increases an alkali dissolution rate by decomposing with an acid, a low molecular weight compound that increases an alkali dissolution rate of the photoresist by decomposing with an acid, and a photoacid generator, and a photoresist having Si atoms in the skeleton of the molecule. Specific examples may include APEX-E (trade name, manufactured by Rohm and Haas Inc.)

Examples of the electron beam resist applied onto the resist underlayer film for lithography of the present invention may include a composition made of a resin containing Si—Si bonds in the main chain and containing an aromatic ring at its end and an acid generator generating an acid by irradiation with electron beams and a composition made of poly(p-hydroxystyrene) in which a hydroxy group is substituted with an organic group containing N-carboxyamine and an acid generator generating an acid by irradiation with electron beams. In the latter electron beam resist composition, the acid generated from the acid generator by the electron beam irradiation is reacted with the N-carboxyaminoxy group of the polymer side chain and the polymer side chain is decomposed into a hydroxy group to exhibit alkali solubility. Consequently, the resist composition is dissolved into an alkali development liquid to form a resist pattern. Examples of the acid generator generating the acid by electron beam irradiation may include halogenated organic compounds such as 1,1-bis[p-chlorophenyl]-2,2,2-trichloroethane, 1,1-bis[p-methoxyphenyl]-2,2,2-trichloroethane, 1,1-bis[p-chlorophenyl]-2,2-dichloroethane, and 2-chloro-6-(trichloromethyl)pyridine, onium salts such as triphenylsulfonium salts and diphenyliodonium salts, and sulfonates such as nitrobenzyltosylate and dinitrobenzyltosylate.

As the development liquid for the resist having the resist underlayer film formed by using the resist underlayer film material for lithography of the present invention, the following aqueous alkali solutions can be used. The aqueous alkali solutions includes solutions of inorganic alkalis such as sodium hydroxide, potassium hydroxide, sodium carbonate, sodium silicate, sodium metasilicate, and aqueous ammonia; primary amines such as ethylamine and n-propylamine; secondary amines such as diethylamine and di-N-butylamine; tertiary amines such as triethylamine and methyldiethylamine; alcoholamines such as dimethylethanolamine and triethanolamine; quaternary ammonium salt such as tetramethylammonium hydroxide, tetraethylammonium hydroxide, and choline; and cyclic amines such as pyrrole and piperidine. To the aqueous solutions of the alkalis described above, an adequate amount of alcohols such as isopropyl alcohol or a surfactant such as a nonionic surfactant can be added and the mixture can be used. Among these development liquids, aqueous solutions of the quaternary ammonium salts are preferable and aqueous solutions of tetramethylammonium hydroxide and choline are further preferable.

As the development liquid, organic solvents can be used. Examples of the organic solvents may include methyl acetate, butyl acetate, ethyl acetate, isopropyl acetate, amyl acetate, isoamyl acetate, ethyl methoxyacetate, ethyl ethoxyacetate, propylene glycol monomethyl ether, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monoethyl ether acetate, diethylene glycol monopropyl ether acetate, diethylene glycol monobutyl ether acetate, diethylene glycol monophenyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl 3-methoxypropionate, ethyl 3-methoxypropionate, ethyl 3-ethoxypropionate, and propyl 3-methoxypropionate. The development liquid can further contains a surfactant and the like. As the conditions of development, the temperature is appropriately selected from 5° C. to 50° C. and the time is appropriately selected from 10 seconds to 600 seconds.

Subsequently, a method for forming the resist pattern of the present invention will be described. The resist underlayer film-forming composition is applied onto a substrate (for example, silicon/silicon dioxide coating, a glass substrate and a transparent substrate such as an ITO substrate) for use in producing precision integrated circuit elements by an appropriate application method such as a spinner and a coater and thereafter the applied composition is cured by baking to form an application type underlayer film. A film thickness of the resist underlayer film is preferably 0.01 μm to 3.0 μm. Conditions for baking after the application are 80° C. to 350° C. for 0.5 minute to 120 minutes. Thereafter, the resist is directly applied onto the resist underlayer film or applied after forming a film made of one layer or several layers of coating material on the resist underlayer film if necessary. Thereafter, the resist is irradiated with light or electron beams through the predetermined mask and is developed, rinsed, and dried to be able to obtain an excellent resist pattern. Post Exposure Bake (PEB) of light or electron beams can also be carried out if necessary. The part of the resist underlayer film where the resist is developed and removed by the previous process is removed by dry etching to be able to form a desired pattern on the substrate.

The exposure light of the photoresist is actinic rays such as near ultraviolet rays, far ultraviolet rays, or extreme ultraviolet rays (for example, EUV, wavelength 13.5 nm) and, for example, light having a wavelength of 248 nm (KrF laser light), 193 nm (ArF laser light), or 157 nm (F₂ laser light) is used. Any light irradiation method can be used without limitation as long as the acid is generated from the photoacid generator. An exposure amount is 1 mJ/cm² to 2,000 mJ/cm², or 10 mJ/cm² to 1,500 mJ/cm², or 50 mJ/cm² to 1,000 mJ/cm².

The electron beam irradiation to the electron beam resist can be carried out by, for example, using an electron beam irradiation device.

In the present invention, a semiconductor device can be produced through steps of forming a resist underlayer film by using the resist underlayer film-forming composition onto a semiconductor substrate; forming a resist film on the underlayer film; forming a resist pattern by irradiation with light or electron beams and development; etching the resist underlayer film by using the resist pattern; and processing the semiconductor substrate by using the patterned resist underlayer film.

When the formation of the finer resist pattern is progressed in the future, the problem of resolution and the problem of resist pattern collapse after development will occur and thus formation of a thinner resist film will be desired. Consequently, the resist pattern thickness sufficient for substrate processing is difficult to be secured. As a result, not only the resist pattern but also the resist underlayer film formed between the resist and the semiconductor substrate to be processed has been required to have the function as a mask at the time of the substrate processing. As the resist underlayer film for such a process, a resist underlayer film for lithography having the selectivity of dry etching rate close to that of the resist, a resist underlayer film for lithography having the selectivity of dry etching rate smaller than that of the resist, or a resist underlayer film for lithography having the selectivity of dry etching rate smaller than that of the semiconductor substrate, which is different from conventional resist underlayer films having high etch rate properties, has been required. Such a resist underlayer film can be provided with the function of anti-reflective properties and thus can also have the function of a conventional anti-reflective coating.

On the other hand, in order to obtain a finer resist pattern, a process has been also started to be used in which the resist pattern and the resist underlayer film at the time of resist underlayer film dry etching are formed more narrowly than the pattern width at the time of resist development. As the resist underlayer film for such a process, the resist underlayer film having the selectivity of dry etching rate close to that of the resist, which is different from conventional high etching rate anti-reflective coatings, has been required. Such a resist underlayer film can be provided with the anti-reflective properties and thus can also have the function of the conventional anti-reflective coating.

In the present invention, after the resist underlayer film of the present invention is formed onto the substrate, the resist can be applied directly onto the resist underlayer film or after a film made of a single layer or several layers of coating material is formed onto the resist underlayer film. This enables the pattern width of the resist to be narrow. Even when the resist is thinly covered in order to prevent pattern collapse, the substrate can be processed by selecting an appropriate etching gas.

More specifically, the semiconductor device can be manufactured through steps of: forming a resist underlayer film onto a semiconductor substrate using the resist underlayer film-forming composition; forming a hard mask on the resist underlayer film using a coating material containing a silicon component and the like or a hard mask (for example, silicon nitride oxide) by vapor deposition; forming a resist film on the hard mask; forming a resist pattern by irradiation with light or an electron beam and development; etching the hard mask using the resist pattern with a halogen-based gas; etching the resist underlayer film using the patterned hard mask with an oxygen-based gas or a hydrogen-based gas; and processing the semiconductor substrate using the patterned resist underlayer film with the halogen-based gas.

In consideration of the effect as the anti-reflective coating, the resist underlayer film-forming composition for lithography of the present invention includes a light absorption site in the skeleton and thus no substances are diffused into the photoresist at the time of drying by heating. The light absorption site has sufficiently large light absorption properties and thus has a high anti-reflection effect.

The resist underlayer film-forming composition for lithography of the present invention has high heat stability, prevents contamination to the upper layer film caused by decomposed substances generated at the time of baking, and can provide an extra temperature margin during the baking process.

Depending on process conditions, the resist underlayer film material for lithography of the present invention can be used as a film that has the anti-reflection function and further has a function that prevents interaction between the substrate and the photoresist or prevents adverse effect on the substrate due to the materials for use in the photoresist or substances generated at the time of light exposure to the photoresist.

The invention in this specification also provides a polymer containing a unit structure Formula (5). As the organic groups described in Formula (5), Formula (1) can be exemplified.

### EXAMPLES

### Synthesis Example 1

To a 100 ml egg-plant shaped flask, 6.0 g of pyrrole (manufactured by Tokyo Chemical Industry Co., Ltd.), 14.1 g of 1-naphthaldehyde (manufactured by Tokyo Chemical Industry Co., Ltd.), 1.8 g of p-toluenesulfonic acid monohydrate (manufactured by Tokyo Chemical Industry Co., Ltd.), and 32.8 g of toluene (manufactured by KANTO CHEMICAL CO., INC.) were charged. Thereafter, the inside of the flask was replaced with nitrogen and then the mixture was stirred at room temperature for about 2 hours. After completion of the reaction, the reaction solution was diluted with 15 g of tetrahydrofuran (manufactured by KANTO CHEMICAL CO., INC.). The diluted liquid was added dropwise into 1,300 g of methanol (manufactured by KANTO CHEMICAL CO., INC.) to reprecipitate the diluted liquid. The obtained precipitate was filtered with suction. The filtered residue was washed with methanol and then dried under reduced pressure at 85° C. overnight to obtain 16.4 g of a novolac resin. The obtained polymer was corresponding to Formula (1-1). The weight average molecular weight Mw measured by GPC in terms of polystyrene was 7,500.

### Synthesis Example 2

To a 200 ml egg-plant shaped flask, 6.0 g of pyrrole (manufactured by Tokyo Chemical Industry Co., Ltd.), 18.6 g of 9-anthracenecarboxaldehyde (manufactured by Tokyo Chemical Industry Co., Ltd.), 1.8 g of p-toluenesulfonic acid monohydrate (manufactured by Tokyo Chemical Industry Co., Ltd.), and 61.6 g of toluene (manufactured by KANTO CHEMICAL CO., INC.) were charged. Thereafter, the inside of the flask was replaced with nitrogen and then 6.0 g of pyrrole (manufactured by Tokyo Chemical Industry Co., Ltd.) was added dropwise with stirring at room temperature. After completion of the dropwise addition, the mixture was stirred at room temperature for about 12 hours. After completion of the reaction, the reaction solution was added dropwise into 1,200 g of hexane (manufactured by KANTO CHEMICAL CO., INC.) to reprecipitate the solution. The obtained precipitate was filtered with suction. The filtered residue was washed with hexane and dried under reduced pressure at 85° C. overnight to obtain 20.3 g of a novolac resin. The obtained polymer was corresponding to Formula (1-2). The weight average molecular weight Mw measured by GPC in terms of polystyrene was 2,000.

### Synthesis Example 3

To a 100 ml egg-plant shaped flask, 2.0 g of pyrrole (manufactured by Tokyo Chemical Industry Co., Ltd.), 7.0 g of 9-pyrenecarboxaldehyde (manufactured by Tokyo Chemical Industry Co., Ltd.), 0.6 g of p-toluenesulfonic acid monohydrate (manufactured by Tokyo Chemical Industry Co., Ltd.), and 28.6 g of toluene (manufactured by KANTO CHEMICAL CO., INC.) were charged. Thereafter, the inside of the flask was replaced with nitrogen and then 2.0 g of pyrrole (manufactured by Tokyo Chemical Industry Co., Ltd.) was added dropwise with stirring at room temperature. After completion of the dropwise addition, the reaction solution was stirred at room temperature for about 1 hour and then further heated to reflux for about 22 hours. After completion of the reaction, 15 g of tetrahydrofuran (manufactured by KANTO CHEMICAL CO., INC.) was added to dissolve the separated solid. The solution was added dropwise into 1,200 g of hexane (manufactured by KANTO CHEMICAL CO., INC.) to reprecipitate the solution. The obtained precipitate was filtered with suction. The filtered residue was washed with hexane and dried under reduced pressure at 85° C. overnight to obtain 6.9 g of a novolac resin. The obtained polymer was corresponding to Formula (1-3). The weight average molecular weight Mw measured by GPC in terms of polystyrene was 900.

### Synthesis Example 4

To a 100 ml egg-plant shaped flask, 6.0 g of pyrrole (manufactured by Tokyo Chemical Industry Co., Ltd.), 10.9 g of 4-hydroxybenzaldehyde (manufactured by Tokyo Chemical Industry Co., Ltd.), 0.17 g of methanesulfonic acid (manufactured by Tokyo Chemical Industry Co., Ltd.), and 51.3 g of propylene glycol monomethyl ether were charged. Thereafter, the inside of the flask was replaced with nitrogen and then 6.0 g of pyrrole (manufactured by Tokyo Chemical Industry Co., Ltd.) was added dropwise with stirring at room temperature. After completion of the dropwise addition, the solution was heated to reflux for about 15 hours. After completion of the reaction, the solution was contacted to an ion-exchange resin to remove methanesulfonic acid to obtain 66.7 g of a novolac resin solution having a solid content of 17.6%. The obtained polymer was corresponding to Formula (1-4). The weight average molecular weight Mw measured by GPC in terms of polystyrene was 660.

### Synthesis Example 5

To a 200 ml egg-plant shaped flask, 7.0 g of pyrrole (manufactured by Tokyo Chemical Industry Co., Ltd.), 13.4 g of 1-naphthaldehyde (manufactured by Tokyo Chemical Industry Co., Ltd.), 3.7 g of 6-hydroxy-2-naphthaldehyde (manufactured by Tokyo Chemical Industry Co., Ltd.), 0.41 g of methanesulfonic acid (manufactured by Tokyo Chemical Industry Co., Ltd.), and 57.3 g of propylene glycol monomethyl ether were charged. Thereafter, the inside of the flask was replaced with nitrogen and 7.0 g of pyrrole (manufactured by Tokyo Chemical Industry Co., Ltd.) was added dropwise with stirring at room temperature. After completion of the dropwise addition, the mixture was stirred at room temperature for about 14 hours. After completion of the reaction, the reaction solution was added dropwise into 1,600 g of methanol (manufactured by KANTO CHEMICAL CO., INC.) to reprecipitate the solution. The obtained precipitate was filtered with suction. The filtered residue was washed with methanol and then dried under reduced pressure at 85° C. overnight to obtain 11.9 g of a novolac resin. The obtained polymer was corresponding to Formula (1-5). The weight average molecular weight Mw measured by GPC in terms of polystyrene was 2,300.

### Synthesis Example 6

To a 100 ml egg-plant shaped flask, 6.0 g of 1-methylpyrrole (manufactured by Tokyo Chemical Industry Co., Ltd.), 11.6 g of 1-naphthaldehyde (manufactured by Tokyo Chemical Industry Co., Ltd.), 0.07 g of methanesulfonic acid (manufactured by Tokyo Chemical Industry Co., Ltd.), and 52.9 g of propylene glycol monomethyl ether acetate were charged. Thereafter, the inside of the flask was replaced with nitrogen and then 6.0 g of 1-methylpyrrole (manufactured by Tokyo Chemical Industry Co., Ltd.) was added dropwise with stirring at room temperature. After completion of the dropwise addition, the mixture was stirred at room temperature for 4 days. After completion of the reaction, the reaction solution was added dropwise into 1,500 g of methanol (manufactured by KANTO CHEMICAL CO., INC.) to reprecipitate the solution. The obtained precipitate was filtered with suction. The filtered residue was washed with methanol and dried under reduced pressure at 85° C. overnight to obtain 12.1 g of a novolac resin. The obtained polymer was corresponding to Formula (1-6). The weight average molecular weight Mw measured by GPC in terms of polystyrene was 2,200.

### Synthesis Example 7

To a 100 ml egg-plant shaped flask, 6.0 g of 1-phenylpyrrole (manufactured by Tokyo Chemical Industry Co., Ltd.), 6.5 g of l-naphthaldehyde (manufactured by Tokyo Chemical Industry Co., Ltd.), and 37.7 g of propylene glycol monomethyl ether acetate were charged. Thereafter, the inside of the flask was replaced with nitrogen and then 0.04 g of methanesulfonic acid (manufactured by Tokyo Chemical Industry Co., Ltd.) was added dropwise with stirring at room temperature. After completion of the dropwise addition, the solution was heated at 110° C. and stirred for about 17 hours. After completion of the reaction, the reaction solution was added dropwise into 1,000 g of methanol (manufactured by KANTO CHEMICAL CO., INC.) to reprecipitate the solution. The obtained precipitate was filtered with suction. The filtered residue was washed with methanol and dried under reduced pressure at 85° C. overnight to obtain 9.5 g of a novolac resin. The obtained polymer was corresponding to Formula (1-7). The weight average molecular weight Mw measured by GPC in terms of polystyrene was 2,500.

### Synthesis Example 8

To a 100 ml egg-plant shaped flask, 7.0 g of 1-phenylpyrrole (manufactured by Tokyo Chemical Industry Co., Ltd.), 6.0 g of 4-hydroxybenzaldehyde (manufactured by Tokyo Chemical Industry Co., Ltd.), and 30.4 g of propylene glycol monomethyl ether acetate were charged. Thereafter, the inside of the flask was replaced with nitrogen and then 0.05 g of methanesulfonic acid (manufactured by Tokyo Chemical Industry Co., Ltd.) was added dropwise with stirring at room temperature. After completion of the dropwise addition, the solution was heated at 110° C. and stirred for about 17 hours. After completion of the reaction, the solution was contacted to an ion-exchange resin to remove methanesulfonic acid to obtain 42.4 g of a novolac resin solution having a solid content of 24.5%. The obtained polymer was corresponding to Formula (1-8). The weight average molecular weight Mw measured by GPC in terms of polystyrene was 2,300.

### Comparative Synthesis Example 1

Under nitrogen atmosphere, to a 100 ml four-necked flask, carbazole (10 g, 0.060 mol, manufactured by Tokyo Chemical Industry Co., Ltd.), benzaldehyde (6.41 g, 0.060 mol, manufactured by JUNSEI CHEMICAL CO., LTD.), p-toluenesulfonic acid monohydrate (1.19 g, 0.060 mol, manufactured by KANTO CHEMICAL CO., INC.) were added and 1,4-dioxane (15 g, manufactured by KANTO CHEMICAL CO., INC.) was added and the mixture was stirred. The mixture was heated to 100° C. to dissolve and to start polymerization. 2 hours later, the solution was left to cool down to 60° C., and then chloroform (50 g, manufactured by KANTO CHEMICAL CO., INC.) was added to dilute the solution, followed by reprecipitating in methanol (250 g, manufactured by KANTO CHEMICAL CO., INC.). The obtained precipitate was filtered and the resultant filter residue was dried with a vacuum dryer at 60° C. for 10 hours and further at 120° C. for 24 hours to obtain 8.64 g of a target macromolecular compound. The macromolecular compound is a polymer containing the unit structure of Formula (4-1). The weight average molecular weight Mw of the macromolecular compound (Formula (4-1)) measured by GPC in terms of polystyrene was 4,000 and the degree of multiple distribution Mw/Mn was 1.69.

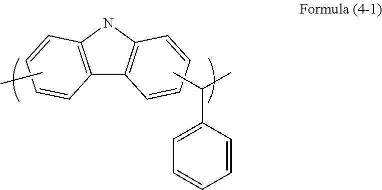

To 0.8 g of the polymer obtained in Synthesis Example 1, 1.0 g of propylene glycol monomethyl ether acetate, 2.5 g of propylene glycol monomethyl ether, 6.4 g of cyclohexanone, 0.16 g of TMOM-BP (Formula (2-22), manufactured by HONSHU CHEMICAL INDUSTRY CO., LTD.) as a crosslinking agent, and 0.016 g of TAG2689 were added to be dissolved to prepare a solution of a resist underlayer film-forming composition for use in a lithography process by a multilayer film.

### Example 2

To 2.0 g of the polymer obtained in Synthesis Example 2, 9.7 g of propylene glycol monomethyl ether acetate, 6.5 g of propylene glycol monomethyl ether, 16.2 g of cyclohexanone, 0.4 g of tetramethoxymethylglycoluril, and 0.04 g of pyridinium p-toluenesulfonate were added to be dissolved to prepare a solution of a resist underlayer film-forming composition for use in a lithography process by a multilayer film.

### Example 3

To 0.8 g of the polymer obtained in Synthesis Example 3, 1.0 g of propylene glycol monomethyl ether acetate, 2.5 g of propylene glycol monomethyl ether, 6.4 g of cyclohexanone, 0.16 g of TMOM-BP (Formula (2-22), manufactured by HONSHU CHEMICAL INDUSTRY CO., LTD.) as a crosslinking agent, and 0.016 g of TAG2689 were added to be dissolved to prepare a solution of a resist underlayer film-forming composition for use in a lithography process by a multilayer film.

### Example 4

To 12.0 g of the polymer solution obtained in Synthesis Example 4, 4.6 g of propylene glycol monomethyl ether acetate, 6.3 g of propylene glycol monomethyl ether, 2.3 g of cyclohexanone, 0.4 g of TMOM-BP (Formula (2-22), manufactured by HONSHU CHEMICAL INDUSTRY CO., LTD.) as a crosslinking agent, and 0.03 g of pyridinium p-toluenesulfonate were added to be dissolved to prepare a solution of a resist underlayer film-forming composition for use in a lithography process by a multilayer film.

### Example 5

To 2.0 g of the polymer obtained in Synthesis Example 5, 11.0 g of propylene glycol monomethyl ether acetate, 6.6 g of propylene glycol monomethyl ether, 4.4 g of cyclohexanone, 0.4 g of TMOM-BP (Formula (2-22), manufactured by HONSHU CHEMICAL INDUSTRY CO., LTD.) as a crosslinking agent, and 0.03 g of pyridinium p-toluenesulfonate were added to be dissolved to prepare a solution of a resist underlayer film-forming composition for use in a lithography process by a multilayer film.

### Example 6

To 1.5 g of the polymer obtained in Synthesis Example 6, 11.5 g of propylene glycol monomethyl ether acetate, 3.3 g of propylene glycol monomethyl ether, 1.6 g of cyclohexanone, 0.3 g of TMOM-BP (Formula (2-22), manufactured by HONSHU CHEMICAL INDUSTRY CO., LTD.) as a crosslinking agent, and 0.02 g of pyridinium p-toluenesulfonate were added to be dissolved to prepare a solution of a resist underlayer film-forming composition for use in a lithography process by a multilayer film.

### Example 7

To 1.5 g of the polymer obtained in Synthesis Example 7, 11.5 g of propylene glycol monomethyl ether acetate, 3.3 g of propylene glycol monomethyl ether, 1.6 g of cyclohexanone, 0.3 g of TMOM-BP (Formula (2-22), manufactured by HONSHU CHEMICAL INDUSTRY CO., LTD.) as a crosslinking agent, and 0.02 g of pyridinium p-toluenesulfonate were added to be dissolved to prepare a solution of a resist underlayer film-forming composition for use in a lithography process by a multilayer film.

### Example 8

To 12.0 g of the polymer solution obtained in Synthesis Example 8, 6.4 g of propylene glycol monomethyl ether acetate, 13.5 g of propylene glycol monomethyl ether, 3.2 g of cyclohexanone, 0.6 g of TMOM-BP (Formula (2-22), manufactured by HONSHU CHEMICAL INDUSTRY CO., LTD.) as a crosslinking agent, and 0.04 g of pyridinium p-toluenesulfonate were added to be dissolved to prepare a solution of a resist underlayer film-forming composition for use in a lithography process by a multilayer film.

### Example 9

To 12.0 g of the polymer solution obtained in Synthesis Example 4, 4.6 g of propylene glycol monomethyl ether acetate, 6.3 g of propylene glycol monomethyl ether, 2.3 g of cyclohexanone, 0.4 g of tetramethoxymethylglycoluril, and 0.03 g of pyridinium p-toluenesulfonate were added to be dissolved to prepare a solution of a resist underlayer film-forming composition for use in a lithography process by a multilayer film.

### Comparative Example 1

To 1.0 g of a macromolecular compound (Formula (4-1)) obtained in Comparative Synthesis Example 1, 0.2 g of tetramethoxymethylglycoluril, 0.02 g of pyridinium p-toluenesulfonate, 0.003 g of MEGAFAC R-30 (manufactured by Dainippon Ink and Chemicals Inc., trade name), 2.3 g of propylene glycol monomethyl ether, 4.6 g of propylene glycol monomethyl ether acetate, and 16.3 g of cyclohexanone were added to prepare a solution. Thereafter, the solution was filtered with a polyethylene microfilter having a pore diameter of 0.10 μm and then further filtered with a polyethylene microfilter having a pore diameter of 0.05 μm to prepare a solution of a resist underlayer film-forming composition for use in a lithography process by a multilayer film.

(Measurement of Optical Parameter)

Each of the resist underlayer film-forming composition solutions prepared in Examples 1 to 9 and Comparative Example 1 was applied onto a silicon wafer using a spin coater. The applied composition solution was baked on a hot plate at 250° C. for 1 minute to form a resist underlayer film (a film thickness of 0.05 μm). The refractive indices (n values) and the optical absorption coefficients (k values, also called damping factors) of these resist underlayer films were measured at wavelength of 193 nm using a spectroscopic ellipsometer. The results are listed in Table 1.

TABLE 1
Refractive index n and optical absorption coefficient k

| | | n | k |
|---|---|---|---|
| | | (193 nm) | (193 nm) |
| Example 1 | Baked film at 250° C. | 1.35 | 0.37 |
| Example 2 | Baked film at 250° C. | 1.54 | 0.43 |
| Example 3 | Baked film at 250° C. | 1.54 | 0.55 |
| Example 4 | Baked film at 250° C. | 1.54 | 0.76 |
| Example 5 | Baked film at 250° C. | 1.35 | 0.36 |
| Example 6 | Baked film at 250° C. | 1.40 | 0.35 |
| Example 7 | Baked film at 250° C. | 1.55 | 0.57 |
| Example 8 | Baked film at 250° C. | 1.64 | 0.85 |
| Example 9 | Baked film at 250° C. | 1.56 | 0.78 |
| Comparative Example 1 | Baked film at 250° C. | 1.38 | 0.38 |

(Elution Test to Photoresist Solvent)

Each of the resist underlayer film-forming composition solutions prepared in Examples 1 to 9 and Comparative Example 1 was applied onto a silicon wafer with a spinner. The applied composition solution was heated on a hot plate at 250° C. for 1 minute to form a resist underlayer film (film thickness 0.2 μm). These resist underlayer films were immersed into solvents for use in the photoresist, for example, ethyl lactate, propylene glycol monomethyl ether, and propylene glycol monomethyl ether acetate. It was confirmed that the resist underlayer films were insoluble to these solvents.

(Embeddability Test)

The resist underlayer film-forming composition solutions for lithography of the present invention obtained in Examples 1 to 9 and Comparative Example 1 were applied onto SiO₂-attached wafer substrates having holes (diameter 0.13 μm, depth 0.7 μm) with a spin coater. The pattern is a pattern in which a distance between a hole center and an adjacent hole center is the same as the diameter of the hole.

After the application with the spin coater, the applied composition solutions were baked on a hot plate at 240° C. for 1 minute to form underlayer films. The sectional shape of the SiO₂-attached water substrate having the holes to which the underlayer film-forming composition for lithography of the present invention obtained in Example 1 was applied was observed using a scanning electron microscope (SEM) to evaluate the embeddability of the underlayer film in the following criteria. The case that the underlayer film was able to be embedded in the holes without voids was determined to be good (listed in Table 2 as “◯”), whereas the case that voids were generated in the holes in the underlayer film was determined to be poor (listed in table 2 as “x”).

TABLE 2
Embeddability test

| | |
|---|---|
| Example 1 | ∘ |
| Example 2 | ∘ |
| Example 3 | ∘ |
| Example 4 | ∘ |
| Example 5 | ∘ |
| Example 6 | ∘ |
| Example 7 | ∘ |
| Example 8 | ∘ |
| Example 9 | ∘ |
| Comparative Example 1 | x |

(Measurement of Dry Etching Rate)

The following etching apparatus and etching gas was used for dry etching rate measurement.

Etching apparatus: RIE-10NR (manufactured by SAMCO INC.)

Etching gas: CF₄

Each of the resist underlayer film-forming composition solutions prepared in Examples 1 to 9 and Comparative Example 1 was applied onto a silicon wafer with a spinner. The applied composition solution was heated on a hot plate at 240° C. for 1 minute to form a resist underlayer film (a film thickness of 0.2 μm). To the resist underlayer film, the dry etching rate was measured using CF₄ gas as the etching gas. A solution prepared by dissolving 0.7 g of the phenol novolac resin in 10 g of propylene glycol monomethyl ether was also applied onto a silicon wafer with a spinner. The applied solution was heated at a temperature of 240° C. for 1 minute to form a phenol novolac resin film. To the resin film, the dry etching rate was measured using CF₄ gas as the etching gas. The dry etching rates of each of the resist underlayer films formed from the resist underlayer film-forming compositions in Examples 1 to 9 and Comparative Example 1 were compared with the dry etching rate of the resin film. The results were listed in Table 3. The dry etching rate ratio in Table 3 is a ratio of the dry etching rate of each of the resist underlayer films to the dry etching rate of the phenol novolac resin film (each of the resist underlayer films)/(phenol novolac resin film).

TABLE 3
Dry etching rate ratio

| | |
|---|---|
| Example 1 | 0.86 |
| Example 2 | 0.83 |
| Example 3 | 0.78 |
| Example 4 | 0.98 |
| Example 5 | 0.88 |
| Example 6 | 0.78 |
| Example 7 | 0.76 |
| Example 8 | 0.79 |
| Example 9 | 1.04 |
| Comparative Example 1 | 0.78 |

From these results, it is found that, different from conventional high etching rate anti-reflective coatings, the resist underlayer film obtained from the resist underlayer film-forming composition according to the present invention can provide an excellent application type resist underlayer film that has the selectivity of dry etching rate close to that of the photoresist or the selectivity of dry etching rate lower than that of the photoresist, the selectivity of dry etching rate lower than that of the semiconductor substrate, and also further has an effect as an anti-reflective coating.

### INDUSTRIAL APPLICABILITY

The present invention can provide an excellent resist underlayer film having the selectivity of dry etching rate close to that of the resist, the selectivity of dry etching rate lower than that of the resist, or the selectivity of dry etching rate lower than that of the semiconductor substrate.

1. A resist underlayer film-forming composition comprising a polymer containing a unit structure of Formula (1): 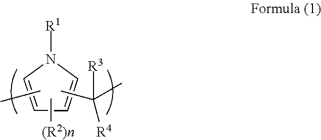
(where R¹ is selected from the group consisting of a hydrogen atom, a C₁₋₁₀ alkyl group, a C₂₋₁₀ alkenyl group, a C₆₋₄₀ aryl group, or a combination thereof, and at this time, the alkyl group, the alkenyl group, or the aryl group optionally contains an ether bond, a ketone bond, or an ester bond; R² is selected from the group consisting of a halogen group, a nitro group, an amino group, a hydroxy group, a C₁₋₁₀ alkyl group, a C₂₋₁₀ alkenyl group, a C₆₋₄₀ aryl group, or a combination thereof, and at this time, the alkyl group, the alkenyl group, or the aryl group optionally contains an ether bond, a ketone bond, or an ester bond; R³ is a hydrogen atom, or a C₆₋₄₀ aryl group or a heterocyclic group optionally substituted with a halogen group, a nitro group, an amino group, a carbonyl group, a C₆₋₄₀ aryl group, or a hydroxy group; R⁴ is a hydrogen atom, or a C₁₋₁₀ alkyl group, a C₆₋₄₀ aryl group, or a heterocyclic group optionally substituted with a halogen group, a nitro group, an amino group, or a hydroxy group; R³ and R⁴ optionally form a ring together with carbon atoms bonded thereto; and n is an integer of 0 to 2).

2. The resist underlayer film-forming composition according to claim 1, wherein in Formula (1), R³ is a benzene ring, a naphthalene ring, an anthracene ring, or a pyrene ring; R⁴ is a hydrogen atom; and n is 0.

3. The resist underlayer film-forming composition according to claim 1, further comprising a crosslinking agent.

4. The resist underlayer film-forming composition according to claim 1, further comprising an acid and/or an acid generator.

5. A resist underlayer film obtained by applying the resist underlayer film-forming composition as claimed in claim 1 onto a semiconductor substrate and baking the applied resist underlayer film-forming composition.

6. A method for forming a resist pattern for use in semiconductor production, the method comprising the step of:
forming an underlayer film by applying the resist underlayer film-forming composition as claimed in claim 1 onto a semiconductor substrate and baking the applied resist underlayer film-forming composition.

7. A method for producing a semiconductor device, the method comprising the steps of:
forming an underlayer film from the resist underlayer film-forming composition as claimed in claim 1 onto a semiconductor substrate;
forming a resist film on the underlayer film;
forming a resist pattern by irradiation with light or an electron beam and development;
etching the underlayer film by using the resist pattern; and
processing the semiconductor substrate by using the patterned underlayer film.

8. A method for producing a semiconductor device, the method comprising the steps of:
forming an underlayer film from the resist underlayer film-forming composition as claimed in claim 1 onto a semiconductor substrate;
forming a hard mask on the underlayer film;
forming a resist film on the hard mask;
forming a resist pattern by irradiation with light or an electron beam and development;
etching the hard mask by using the resist pattern;
etching the underlayer film by using the patterned hard mask; and
processing the semiconductor substrate by using the patterned underlayer film.

9. The method for producing a semiconductor device according to claim 8, wherein the hard mask is formed by vapor deposition of an inorganic substance.

10. A polymer containing a unit structure of Formula (5): 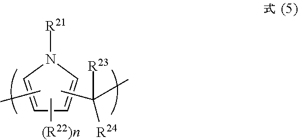
(where R²¹ is selected from the group consisting of a hydrogen atom, a C₁₋₁₀ alkyl group, a C₂₋₁₀ alkenyl group, a C₆₋₄₀ aryl group, or a combination thereof, and at this time, the alkyl group, the alkenyl group, or the aryl group optionally contains an ether bond, a ketone bond, or an ester bond; R²² is selected from the group consisting of a halogen group, a nitro group, an amino group, a hydroxy group, a C₁₋₁₀ alkyl group, a C₂₋₁₀ alkenyl group, a C₆₋₄₀ aryl group, or a combination thereof, and at this time, the alkyl group, the alkenyl group, or the aryl group optionally contains an ether bond, a ketone bond, or an ester bond; R²³ is a hydrogen atom, or a C₆₋₄₀ aryl group or a heterocyclic group optionally substituted with a halogen group, a nitro group, an amino group, a carbonyl group, a C₆₋₄₀ aryl group, or a hydroxy group; R²⁴ is a C₁₋₁₀ alkyl group, a C₆₋₄₀ aryl group, or a heterocyclic group optionally substituted with a halogen group, a nitro group, an amino group, or a hydroxy group; R²³ and R²⁴ optionally form a ring together with carbon atoms bonded thereto; and n is an integer of 0 to 2).
